(19) United States
(12) Patent Application Publication
(10) Pub. No.: US 2013/0084666 A1
(43) Pub. Date: Apr. 4, 2013

(54) METHOD FOR MANUFACTURING LIGHT EMITTING DEVICE

(71) Applicant: Hidemasa Oshige, Yokohama-shi (JP)

(72) Inventor: Hidemasa Oshige, Yokohama-shi (JP)

(73) Assignee: CANON KABUSHIKI KAISHA, Tokyo (JP)

(21) Appl. No.: 13/619,140

(22) Filed: Sep. 14, 2012

(30) Foreign Application Priority Data
Sep. 30, 2011 (JP) 2011-217445

(51) Int. Cl. H01L 51/56

(52) U.S. Cl. 438/35; 257/E51.022

(57) ABSTRACT

Provided is a method for manufacturing a light emitting device that includes, on a substrate, a plurality of lower electrodes, a first, a second and a third organic layers each formed on one of the lower electrodes to emit light of a color different from each other, and a upper electrode opposite to the lower electrodes sandwiching the first, the second or the third organic layer. The method includes forming the first organic layer on the plurality of lower electrodes, removing the first organic layer on a certain lower electrode to expose the lower electrode, and then forming a new organic layer on the exposed lower electrode, and repeats this processing for the second and third organic layers.

### BACKGROUND OF THE INVENTION

1. Field of the Invention

The present invention relates to a method for manufacturing a light emitting device. More specifically, the invention relates to a method for manufacturing a light emitting device such as a display device or an illumination device, including an organic electroluminescent (organic EL) element.

2. Description of the Related Art

Recently, as a flat panel display, an organic EL display device that is a self-luminous type device has been a focus of attention. The organic EL display device means a display device that uses an organic EL element including a pair of electrodes and an organic layer arranged between the pair of electrodes as a display element. The organic EL display device that executes color displaying employs a configuration where an organic EL element for emitting white light is combined with color filters of a plurality of colors, or a configuration where a plurality of types of organic EL elements for emitting colors different from one another, such as red, green, and blue, is arranged.

Japanese Patent Application Laid-Open No. 2003-36971 discusses a method for patterning the organic layers by using photolithography as a method for forming organic layers of a plurality of types of organic EL elements in predetermined positions with high accuracy.

Specifically, a first light emitting layer for emitting light of a first color is formed by coating on a whole surface of a substrate, and a photoresist layer (peeling layer) is formed thereon. Then, after the photoresist layer is patterned by photolithography to be left only in an area where the first light emitting layer is to be left, the first light emitting layer is selectively etched by using the photoresist layer as a mask. As a result, the first light emitting layer is formed in a predetermined area.

Then, while the photoresist used for patterning the first light emitting layer is left, a second light emitting layer for emitting light of a second color is formed by coating on the whole surface of the substrate, and the photoresist layer is peeled (lifted off) together with the second light emitting layer formed thereon. Further, a photoresist layer (peeling layer) is formed on the first light emitting layer and the second light emitting layer, and the photoresist layer is then patterned by photolithography to be left only in an area where the first light emitting layer and the second light emitting layer are to be left. By using this photoresist layer as a mask, the second light emitting layer is removed by etching. Thus, the second light emitting layer is patterned to be formed in a predetermined area.

Then, while the photoresist layer used for patterning the second light emitting layer is left, a third light emitting layer for emitting light of a third color is formed by coating on the whole surface of the substrate, and the photoresist layer is peeled (lifted off) together with the third light emitting layer formed thereon. Thus, the third light emitting layer is patterned to be formed in a predetermined area.

The use of photolithography enables formation of the first light emitting layer, the second light emitting layer, and the third light emitting layer for emitting light of different colors in predetermined positions with high positional accuracy.

US Laid-Open Patent No. 2010-0117936 also discusses a method for manufacturing an organic EL element by similar photolithography. According to this method, a light emitting layer is selectively removed by irradiation with a laser beam.

However, in a conventional photolithography process, an organic EL layer is patterned in a predetermined position for each color. This processing is repeated for three colors, and organic LE layers are arrayed. Accordingly, a lower electrode surface where the organic EL layer of the third color is formed is subjected twice to etching gas or etchant during an etching process of removing the previously formed organic EL layers of two colors. In the method for removing, by etching, the organic EL layer with the laser beam, a lower electrode surface where an organic EL layer of a third color is formed is irradiated twice with the laser beam.

One of the processes of removing the organic EL layers is dry etching using oxygen gas, tetrafluoromethane (CF4) gas, or sulfur hexafluoride (SF6) gas. Exposure of the lower electrode to the dry etching process may cause the following problems.

The first problem is that reaction between an electrode material and etching gas generates a compound on the surface of the lower electrode and re-adhesion of the reaction product onto the surface of the lower electrode lowers a cleanliness of the lower electrode surface. The lowered cleanliness of the lower electrode surface leads to deterioration of hole or electron injection characteristics from the lower electrode into the organic layer. Inconsequence, reduction of light emission efficiency, an increase of power consumption due to a higher driving voltage, or a display failure such as uneven light emission occurs. Especially, when an alloy material containing Al or Ag is used for the lower electrode, a reaction compound with the etching gas is easily generated on the lower electrode surface, and such a problem is conspicuous. When a transparent conductive film of an oxide such as indium tin oxide (ITO), indium zinc oxide (IZO), or magnesium oxide (MnOₓ) is formed in the lower electrode surface, while no reaction compound is generated, a surface oxidation degree of the oxide transparent conductive film changes, consequently deteriorating the hole or electron injection characteristics into the organic layer.

A second problem is that due to etching of the surface of the lower electrode, surface smoothness drops to cause local concentration of current, thereby reducing light emission efficiency. At worst, short-circuiting between the lower electrode and the upper electrode occurs to cause no light emission.

Above described lowering degree of the cleanliness or the smoothness of the lower electrode surface is proportional to a period of time where the lower electrode surface is exposed to the dry etching process. Accordingly, the cleanliness or the smoothness drops most on the lower electrode surface where the organic EL layer of the third color is formed. As a result, reduction of luminous efficiency or display failures frequently occur in the organic EL element where the organic EL layer of the third color is formed, thus lowering yield of the organic EL display device. In the method for etching the organic EL layer with the laser beam, the lower electrode surface is similarly damaged by the irradiation with the laser beam. Thus, charge injection characteristics and smoothness of the lower electrodes are different between the organic EL layer of the second color and the organic EL layer of the third color.

### SUMMARY OF THE INVENTION

According to an aspect of the present invention, there is provided a method for manufacturing a light emitting device that includes, on a substrate, a plurality of lower electrodes, a first, a second and a third organic layers each formed on one of the lower electrodes to emit light of a color different from each other, and a upper electrode opposite to the lower electrodes sandwiching the first, the second or the third organic layer. The method includes (1) forming the plurality of lower electrodes on the substrate; (2) forming the first organic layer on the plurality of lower electrodes; (3) removing the first organic layer on a certain lower electrode included in the plurality of lower electrodes to expose the lower electrode while leaving the first organic layer on the lower electrodes other than the certain lower electrode, and then forming the second organic layer on the exposed lower electrode; (4) removing the first organic layer on another certain lower electrode different from the certain lower electrode to expose the lower electrode while leaving the first organic layer on the lower electrodes other than the certain and the another certain lower electrodes, and then forming the third organic layer on the exposed lower electrode; and (5) forming the upper electrodes on the first to third organic layers.

According to the manufacturing method of the present invention, since the number of times of subjecting the lower electrode surface on which the organic layer of the third color is formed to the dry etching process or the etching process with the laser beam is reduced, the lowering degree of the cleanliness or the smoothness of the lower electrode surface of the organic layer of the third color is reduced. Even in the case of forming an organic layer of a fourth color or after, damaging of the lower electrode can be prevented by repeating the same processing as that of the third color. As a result, display failures of the organic EL display device can be reduced, light emission efficiency can be improved, and a driving voltage can be reduced.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIGS. 1A, 1B, 1C, 1D, 1E, 1F, and 1G illustrate amethod for manufacturing a light emitting device according to a first exemplary embodiment of the present invention.

FIGS. 2A, 2B, 2C, 2D, 2E, 2F, 2G, and 2H illustrate a method for manufacturing a light emitting device according to a second exemplary embodiment of the present invention.

FIGS. 3A, 3B, 3C, 3D, 3E, 3F, 3G, 3H, and 3J illustrate a method for manufacturing a light emitting device according to a third exemplary embodiment of the present invention.

FIG. 4 is a top view illustrating an organic EL display device according to an exemplary embodiment of the present invention.

### DESCRIPTION OF THE EMBODIMENTS

Various exemplary embodiments, features, and aspects of the invention will be described in detail below with reference to the drawings.

A light emitting device manufactured by a method according to the present invention includes a light emitting element represented by an organic electroluminescent element. The organic electroluminescent element includes a layer containing an organic substance between a lower electrode and an upper electrode, and the organic substance includes an electroluminescent material either one of red, blue, or green. Three types of organic EL elements that emit light of these different colors are integrated into one set to constitute a pixel. In the case of an active matrix display device, a plurality of lower electrodes is separately formed on a substrate, and voltages are independently applied. Upper electrode is common to all light emitting elements. In the case of a passive matrix, upper electrodes and lower electrodes are formed into striped shapes to intersect each other.

In the light emitting device according to the present invention, a plurality of lower electrodes is first formed on the substrate, and an organic layer of first color is formed thereon. Then, the organic layer of the first color on a certain lower electrode is removed to expose a lower electrode below. An organic layer of a second color is formed on the exposed lower electrode. Then, a lower electrode different from the lower electrode on which the organic layer of the second color has been formed, namely, the organic layer of the first color on another lower electrode, is removed to expose the lower electrode. However, the organic layer of the first color on all the lower electrodes are not removed, but the organic layer of the first color on some lower electrodes are left. Then, an organic layer of a third color is formed on the exposed lower electrode, and lastly an upper electrode is formed.

In other words, the organic layers of the first colors are first formed on all the lower electrodes, and then the organic layer of the first color on the lower electrodes is removed to form the organic layers of the second and third colors in the removed positions. Processing is similar for forming organic layers of a fourth color and further multiple colors. The organic layer of the first color located on the lower electrode on which above organic layer is to be formed is removed to form a new organic layer.

According to this method, the lower electrode is covered with the first organic layer formed first. The first organic layer is removed at a stage of forming a new organic layer, and a new organic layer is formed thereon. The lower electrode is exposed only once when the first organic layer is removed. The number of exposing times is one for all the organic layers of a second color and after. Since the lower electrode is exposed by removal of the first organic layer in any case, exposed atmosphere and exposure time can be similar. As a result, conditions of lower electrode surfaces during film formation are all similar for the second organic layer and after, and luminous efficiency and other characteristics are uniform.

Hereinafter, three exemplary embodiments of the present invention will be described with reference to the accompanying drawings. For portions not illustrated or described, a known technology in the related field can be applied. The three embodiments are exemplary, and thus in no way limitative of the present invention.

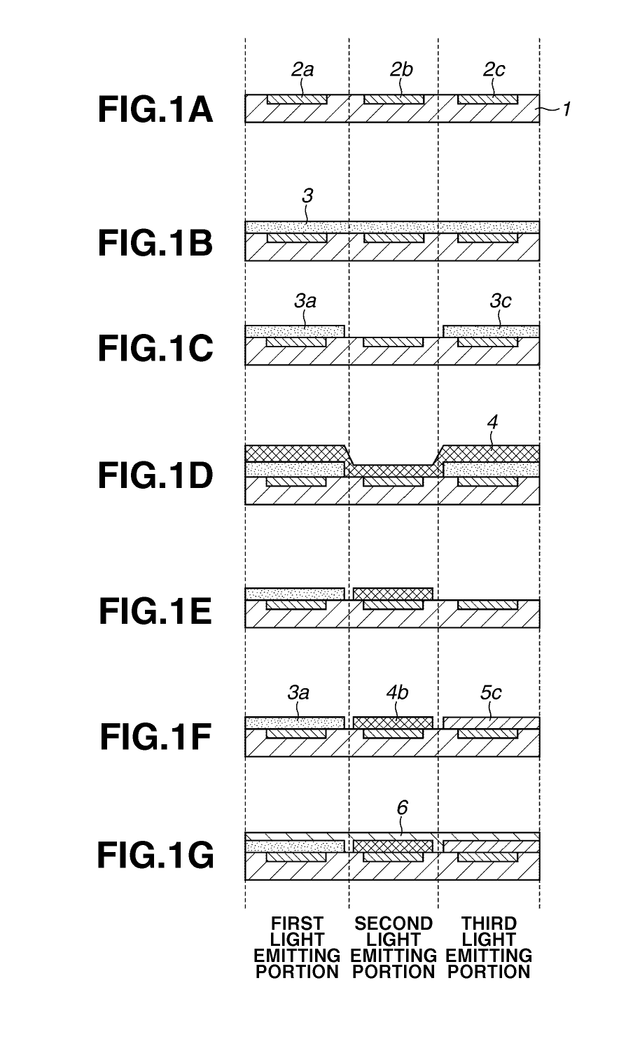

The first exemplary embodiment will be described. FIGS. 1A to 1G illustrate a manufacturing process of an organic EL display device according to the first exemplary embodiment. Specifically, FIG. 1A illustrates a state where lower electrodes (2a, 2b, and 2c) are formed on a substrate. FIG. 1B illustrates a state where a first organic layer (3) is formed on the lower electrodes. FIGS. 1C and 1D illustrate a state where the organic layer is removed from a certain lower electrode (2b) to expose the lower electrode and a state where second organic layers (4) are formed on the exposed lower electrode (2b) and the first organic layer left without being removed. FIGS. 1E and 1F illustrate a state where the first organic layer is removed from another certain lower electrode (2c) to expose the lower electrode and a state where a third organic layer (5c) is formed on the exposed lower electrode. FIG. 1G illustrates a state where an upper electrode (6) is formed on the fist organic layer and the second organic layer left without being removed in the step illustrated in FIG. 1E and the third organic layer.

In the manufacturing method according to the present exemplary embodiment, all the first to third organic layers are pattern-formed by etching.

A substrate 1 is an insulating substrate such as glass or Si wafer. Other materials may be used without any limitation as long as they can endure a temperature during the manufacturing process of the organic EL element and satisfy use conditions as a display device.

Before the formation of the lower electrodes 2a, 2b, and 2c, a driving circuit (not illustrated) for driving the organic EL display device is provided on the substrate 1 when necessary. Others, such as a planarization layer for planarizing concave-convex portion formed by the driving circuit and a separation layer for separating the electrodes and sectionalizing a light emitting area may be arranged if necessary.

A plurality of lower electrodes 2a, 2b, and 2c is formed on the substrate 1 as illustrated in FIG. 1A. Areas where the lower electrodes 2a, 2b, and 2c have been formed are display areas of the organic EL display device.

Each of the lower electrodes 2a, 2b, and 2c constitutes a lower electrode of the organic EL element. Through the following process, organic layers of three different colors are formed on the three lower electrodes 2a to 2c. Organic EL elements that use the first, second, and third organic layers are respectively formed on the lower electrodes 2a, 2b, and 2c. An area where the organic El element including the first organic layer is formed is referred to as a first light emitting portion. An area where the organic El element including the second organic layer is formed is referred to as a second light emitting portion. An area where the organic El element including the third organic layer is formed is referred to as a third light emitting portion. Above three light emitting portions constitute a pixel.

The lower electrodes 2a, 2b, and 2c are formed by using a conductive material. For the conductive materials, a metal material such as Al or Ag, a conductive oxide material such as ITO, IZO, or MoOx, or a laminated film thereof may be used. The lower electrode may be formed by covering a surface of a metal member such as Al or Ag with an aluminum alloy film, a silver alloy film, or a transparent conductive oxide film. By depositing such conductive materials on the substrate 1, and etching the films by using a photoresist, patterned by photolithography or an ink jet method, as a mask, the lower electrodes 2a, 2b, and 2c can simultaneously be formed.

The lower electrodes 2a, 2b, and 2c may be formed of conductive materials partially or all different from each other.

Then, in at least the display areas of the substrate 1 where the lower electrodes 2a, 2b, and 2c have been formed, a first organic layer 3 is formed by vacuum deposition or coating as illustrated in FIG. 1B.

For materials of the first, second, and third organic layers 3, 4, and 5, low-molecular system or high-molecular system light emitting materials may selectively be used. Each organic layer may include a plurality of layers formed by stacking a hole injection layer, a hole transport layer, an electron transport layer, or an electron injection layer on a layer made of a light emitting material.

Then, a first processing step for selectively removing the first organic layer 3 located on the lower electrode 2b of the second light emitting portion is executed as illustrated in FIG. 1C.

In the first processing step, as illustrated in FIG. 1C, patterning is carried out to leave not only the first organic layer 3a of the first light emitting portion but also the first organic layer 3c of the third light emitting portion. As a patterning method, a photoresist film is formed into a desired pattern by photolithography or the ink jet method, and the first organic layer 3 is etched to be removed by using the film as a mask.

For an etching method of the first organic layer 3, various dry etching methods such as reactive ion etching (RIE) or plasma etching using, as etching gas, oxygen gas or fluoride gas such as CF4 or SF6, or a wet etching method using solution in which the first organic layer 3 is soluble may be used. The dry etching method is more desirable than the wet etching method because a retraction amount due to side etching of the first organic layer is smaller.

In the first processing step, the lower electrode 2b of the second light emitting portion is exposed to etching gas or etchant to be damaged on the surface to some extent. However, the lower electrode 2a of the first light emitting portion and the lower electrode 2c of the third light emitting portion are covered with the first organic layer 3 to be prevented from being damaged.

After the end of the first processing step, a second organic layer 4 for emitting light of a color different from that of the first organic layer 3 is formed by vacuum deposition or coating as illustrated in FIG. 1D.

In the case of formation by vacuum deposition, second organic layers 4 may selectively be formed only in the second light emitting portion and the third light emitting portion while covering the first light emitting portion with a mask. In the case of deposition or coating not using any mask, second organic layers 4 are formed in whole display areas.

For the second organic layer 4, as in the case of the first organic layer 3, a low-molecular system or high-molecular system light emitting material may be used. A laminated film configuration similar to that of the first organic layer 3 may be employed.

Next, a second processing step for patterning the second organic layer 4 is carried out as illustrated in FIG. 1E. For a patterning method, a method similar to that of the first processing step may be used.

In the second processing step, as illustrated in FIG. 1E, while the second organic layer 4 of the second light emitting portion is left, the second organic layer 4 and the first organic layer 3c of the third light emitting portion are sequentially removed to expose the lower electrode 2c.

It is desirable for etching of the first organic layer 3c in the second processing step to be executed under the same conditions as those of the first processing step. In other words, it is desirable for etching to be executed by using the same etching gas or the same etchant under conditions of equal etching time and equal temperatures so that influences on the lower electrodes can be similar.

When the second organic layer 4 is formed on the whole surface during the formation of the second organic layer 4 as illustrated in FIG. 1D, a second organic layer 4 is also present in the first light emitting portion. In the first light emitting portion, only the second organic layer 4 must be removed while leaving the first organic layer 3a. In this case, a two-stage patterning process may be carried out. Specifically, first, the second organic layers 4 formed in the first light emitting portion and the third light emitting portion are etched to be removed. Then, only the first organic layer 3c of the third light emitting portion is selectively removed while leaving the first organic layer 3a of the first light emitting portion. In this case, the first organic layer 3a of the first light emitting portion may be etched somewhat depending on an etching selection ratio during etching of the second organic layer 4. In view of this film thickness reduction, it is desirable to form the first organic layer 3 thicker beforehand.

Then, a third organic layer 5 for emitting light of a color different from those of the first organic layer 3 and the second organic layer 4 are formed by vacuum deposition or coating as illustrated in FIG. 1F. By mask deposition, the third organic layer 5 may be formed only on the lower electrode 2c of the third light emitting portion.

When the third organic layer 5 is formed on the whole surface from the first light emitting portion to the third light emitting portion, by a similar method to that of the first and second processing steps, patterning is carried out to remove the third organic layers 5 from the first light emitting portion and the second light emitting portion while leaving the third organic layer 5c of the third light emitting portion. In this case, the first organic layer 3a and the second organic layer 4b formed in the first light emitting portion and the second light emitting portion are reduced somewhat by etching. Thus, in view of this film thickness reduction by etching, it is desirable to form the first organic layer thicker beforehand. For a patterning method, a method similar to that of the first and second processing steps may be used. Material selection and a laminated film configuration of the third organic layer 5 may be similar to those of the first organic layer 3 and the second organic layer.

Lastly, the organic EL display device is completed by forming an upper electrode 6 on the whole surface of an area including the patterned first to third organic layers 3a, 4b, and 5c as illustrated in FIG. 1G. A common organic compound layer may be formed between the first to third organic layers 3a, 4b, and 5c and the upper electrode 6.

For the upper electrode 6, a metal material such as Al or Ag, a conductive oxide material such as ITO, or IZO, or a laminated film thereof can be used. To output light emitted from the organic layer to the outside, a transparent or semitransparent material is used for at least one of the lower electrodes 2a, 2b, and 2c and the upper electrode 6. In this case, a material having transmittance of 80% or higher with respect to visible light is referred to as transparent, and a material having transmittance of 20 to 80% with respect to visible light is referred to as semitransparent. The upper electrode 6 can be formed by vacuum deposition such as vapor deposition or sputtering. A material having conductivity which do not give any damage to the organic layer during formation is desirable.

The organic EL element deteriorates due to moisture. Though not illustrated in FIGS. 1A to 1G, to prevent infiltration of the moisture into the organic EL element, it is desirable for a sealing structure to be formed on the upper electrode 6. For the sealing structure, a film sealing configuration where a highly moisture-proof sealing film such as a silicon nitride film is formed singly or laminated, or a cap sealing configuration where the surroundings of a highly moisture-proof sealing film such as glass are fixed to the substrate 1 by adhesives or glass flits can be employed. In this case, an infiltration path of the moisture from the outside can be cut off by forming an area having no organic material in a peripheral part of the substrate 1 to prevent connection of the area formed of the organic EL element to the outer side (outside) of the sealing configuration by any organic material.

Thus, the color organic EL display device where the first to third organic layers 3a, 4b, and 5c are respectively formed in the predetermined light emitting portions to emit lights of different colors can be acquired.

According to the present embodiment, as illustrated in FIG. 1C, the etching of the first processing step is carried out to leave the organic layer 3c in the third light emitting portion, and only the organic layer 2b in the second light emitting portion is exposed. The organic layer 2c in the third light emitting portion is exposed during the second processing step illustrated in FIG. 1E, and exposed to the etching gas to be damaged. Consequently, cleanliness or smoothness deteriorates. However, in the first processing step, no exposure occurs, and thus damage by exposure occurs only once. As a result, between the lower electrode 2b of the second light emitting portion and the lower electrode 2c of the third light emitting portion, the numbers of processing times where damage occurs before formation of organic layers thereon are equal. Thus, the organic layer 4b of the second light emitting portion and the organic layer 5c of the third light emitting layer are formed on substrates approximately equal in cleanliness and smoothness, and characteristics such as light emission efficiency are uniform.

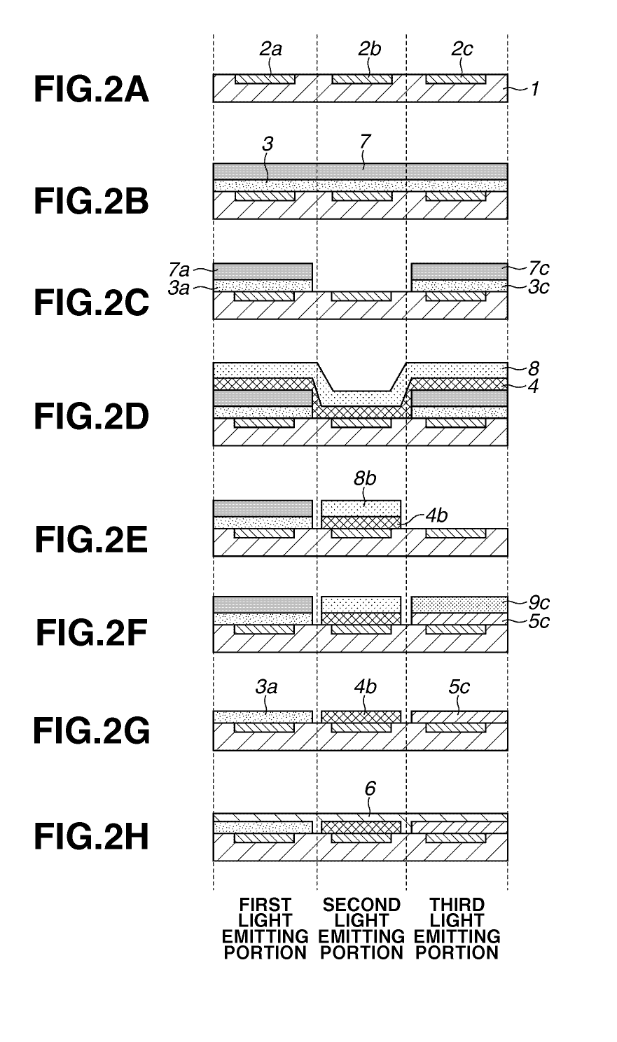

A second exemplary embodiment will be described. FIGS. 2A to 2H illustrate a manufacturing process of an organic EL display device according to the second exemplary embodiment. Specifically, FIG. 2A illustrates a state where lower electrodes (2a, 2b, and 2c) are formed on a substrate. FIG. 2B illustrates a state where a first organic layer (3) and a first protective layer (7) are formed on the lower electrodes. FIG. 2C illustrates a state where the organic layer is removed from a certain lower electrode (2b) to expose the lower electrode. FIG. 2D illustrates a state where second organic layers (4) and a second protective layer (8) are formed on the exposed lower electrode (2b). FIG. 2E illustrates a state where the first organic layer is removed from another certain lower electrode (2c). FIG. 2F illustrates a state where a third organic layer (5c) and a third protective layer (9) are formed on the exposed lower electrode (2c). FIG. 2G illustrates a state where the protective layer has been removed. FIG. 2H illustrates a case where an upper electrode (6) is formed.

The manufacturing method according to the present exemplary embodiment is different from that of the first exemplary embodiment in inclusion of steps of respectively forming the protective layers on the first, second, and third organic layers. All of the organic layers and the protective layers are pattern-formed by etching.

Referring to FIGS. 2A to 2H, the method for manufacturing an organic EL device according to the present embodiment will be described. However, description of portions similar to those of the first exemplary embodiment will be omitted.

As in the case of the first exemplary embodiment, lower electrodes 2a, 2b, and 2c are formed on a substrate 1 as illustrated in FIG. 2A.

After the formation of the lower electrodes 2a, 2b and 2c on the substrate 1 as illustrated in FIG. 2A, a first organic layer 3 and a first protective layer 7 are formed in this order by vacuum deposition or coating as illustrated in FIG. 2B.

For the first protective layer 7, an arbitrary material can be used as long as it can protect the first organic layer 3 from a subsequent patterning process or moisture in an environment. A metal material such as silicon or aluminum, an inorganic material such as a silicon nitride film, a silicon oxide film, or an aluminum nitride film, or organic resin such as polyimide or acrylic can be used. Especially, the use of a highly moisture-proof silicon nitride film is desirable in terms of moisture blocking performance. When the metal material or the inorganic material is used, the first protective layer 7 can be formed by known vacuum deposition such as vapor deposition or sputtering. When the organic resin is used, the first protective layer 7 can be formed by known vacuum deposition such as vapor deposition or coating such as spin coating.

Then, a first processing step for removing the first protective layer 7 and the first organic layer 3 at least located on the lower electrode of the second light emitting portion is executed as illustrated in FIG. 2C. In this case, as illustrated in FIG. 2C, patterning is carried out so that the first protective layer 7a and 7b, and the first organic layer 3a and 3b of the first light emitting portion and the third light emitting portion are left.

As a patterning method, a protective film such as a photoresist film is formed into a desired pattern by photolithography or the ink jet method, and by using the film as a mask, the first protective layer and the first organic layer is sequentially and partially etched to be removed.

For an etching method of the first protective layer 7, various dry etching methods such as RIE or plasma etching using, as etching gas, fluoride gas such as CF4 or SF6, or a wet etching method using solution in which the first protective layer 7 is soluble may be used. The dry etching method is more desirable because a retraction amount due to side etching of the first organic layer is small. Especially the use of RIE is desirable.

When the first protective layer 7 is a silicon film, a silicon oxide film, or a silicon nitride film, RIE using fluoride gas such as CF4, SF6 or CHF3 as etching gas can be used. When the first protective layer 7 is an aluminum film or a titanium film, RIE using chlorine gas or boron trichloride gas can be used. When the first protective layer 7 is an organic resin, RIE using oxygen gas can be used.

After the removal of the first protective layer 7 by etching, the etching gas is switched to oxygen gas to remove, by etching, the exposed first organic layer 3 by RIE. When the organic resin is used for the first protective layer 7, the first protective layer 7 and the first organic layer 3 can be removed en bloc by etching during the same process. In the first processing step, the lower electrode 2c of the third light emitting portion is not subjected to the etching process because it is covered with the first organic layer and the first protective layer 7.

Then, a second organic layer 4 for emitting light of a color different from that of the first organic layer 3 and a second protective layer 8 are sequentially formed by vacuum deposition or coating. The second organic layer 4 and the second protective layer 8 can be formed on the whole surface of all the areas of the first to third light emitting portions as illustrated in FIG. 2D. However, by mask deposition, the second organic layer 4 and the second protective layer 8 can be formed only on the lower electrode 2b of the second light emitting portion.

The second protective layer 8 may be formed by using the same material and the same method as those of the first protective layer 7. Using similar materials and setting equal thicknesses for the first protective layer 7 and the second protective layer 8 are suitable because the protective layers can be removed by a single process in a subsequent removal step.

Then, a second processing step for patterning the second protective layer 8 and the second organic layer 4 is carried out as illustrated in FIG. 2E. For a patterning method, a similar method to that for the first processing step may be used.

In the second processing step, as illustrated in FIG. 2E, at least the first protective layer 7c and the second protective layer 8c and the first organic layer 3c and the second organic layer 4c of the third light emitting portion are removed to expose the lower electrode 2c of the third light emitting portion, and patterning is carried out to leave the second protective layer 8b and the second organic layer 4b of the second light emitting portion.

When the second organic layer 4 and the second protective layer 8 have been formed in the first light emitting portion and the third light emitting portion in the previous step illustrated in FIG. 2D, only the second protective layer and the second organic layer must be removed by etching while leaving the first protective layer 7a and the first organic layer 3a on the lower electrode of the first light emitting portion, and the second protective layer, the second organic layer, the first protective layer, and the first organic layer of the third light emitting portion must all be removed. In this case, a two-stage patterning process may be carried out. Specifically, first, the second protective layers and the second organic layers formed in the first light emitting portion and the third light emitting portion are sequentially etched to be removed. Then, the first protective layer and the first organic layer on the lower electrode of the third light emitting portion are sequentially etched to be removed.

Then, a third organic layer 5 and a third protective layer 9 for emitting light of colors different from those of the first organic layer 3 and the second organic layer 4 are sequentially formed on at least the lower electrode of the third light emitting portion by vacuum deposition or coating as illustrated in FIG. 2F.

The third protective layer 9 may be formed by using the same material and the same method as those of the first protective layer 7 and the second protective layer 8. Using materials and setting thicknesses similar and equal to those of the first protective layer and the second protective layer are suitable because the protective layers can be removed by a single process in a subsequent removal step. Though not illustrated, the third organic layer 5 and the third protective layer 9 can be formed on the whole surface of all the areas of the first to third light emitting portions. In such a case, by a similar method to that of the first and second processing steps, patterning is carried out to leave the third protective layer 9c and the third organic layer 5c while removing the third protective layer and the third organic layer 5 from the first light emitting portion and the second light emitting portion. For a patterning method, a similar method to that for the first and second processing steps may be used.

Then, a protective layer removal step for removing the first protective layer 7a, the second protective layer 8b, and the third organic layer 9c formed on the respective organic layers is executed as illustrated in FIG. 2G. In the protective layer removal step, when the protective layer is a silicon film, a silicon nitride film, or a silicon oxide film, RIE using fluoride gas such as CF4, SF6 or CHF3 may be used. When the protective layer is an aluminum film or a titanium film, RIE using chlorine gas or boron trichloride gas can be used. When the protective layer is an organic resin, RIE using oxygen gas may be used. In this case, the first, second, and third organic layers formed in the respective emitting portions are reduced somewhat by etching. Thus, in view of this film thickness reduction by etching, it is desirable to form each organic layer thicker beforehand.

Lastly, the organic EL display device is completed by forming an upper electrode 6 on the whole surface of an area including the patterned first to third organic layers 3a, 4b, and 5c as illustrated in FIG. 2H.

As in the case of the first exemplary embodiment, in the present exemplary embodiment, between the lower electrode 2b of the second light emitting portion and the lower electrode 2c of the third light emitting portion, the numbers of processing times where etching damage occurs before formation of organic layers thereon are equal. Thus, the organic layer 4b of the second light emitting portion and the organic layer 5c of the third light emitting portion are formed on substrates approximately equal in nature, and light emission characteristics are uniform.

In the present exemplary embodiment, each organic layer is covered with the protective layer immediately after its formation. This prevents the first organic layer surface (upper surface) from being exposed to etching gas during the patterning step (between FIGS. 2D and 2E) of the second organic layer. Further, during the patterning step (between FIGS. 2E and 2F) of the third organic layer, the first organic layer and the second organic layer are covered with the protective layers. This prevents exposure to etching gas. When the surface of the organic layer is damaged by etching, an interface with the upper electrode is contaminated or becomes unsmooth, consequently reducing carrier injection characteristics. The inclusion of the protective layer can prevent this phenomenon.

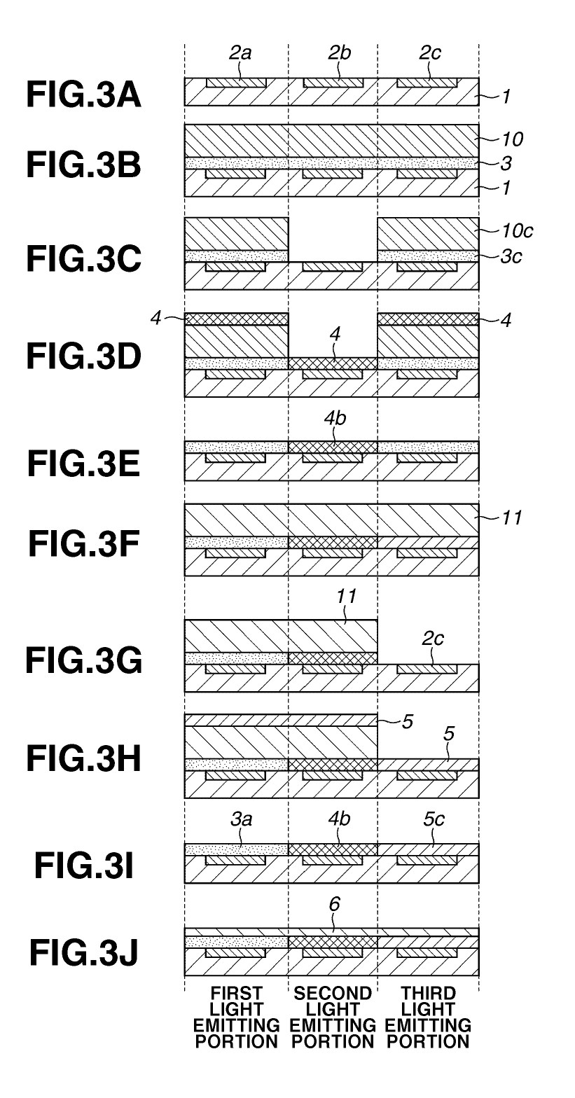

A third exemplary embodiment will be described. FIGS. 3A to 3J illustrate a manufacturing process of an organic EL display device according to the third exemplary embodiment. Specifically, FIG. 3A illustrates a state where lower electrodes (2a, 2b, and 2c) are formed on a substrate. FIG. 3B illustrates a state where a first organic layer (3) is formed on the lower electrode and a peeling layer (10) is formed thereon. FIG. 3C illustrates a state where the peeling layer is patterned and the organic layer is removed from the lower electrode (2b) having no peeling layer to expose the lower electrode. FIG. 3D illustrates a state where a second organic layer (4) is formed on the exposed lower electrode (2b). FIG. 3E illustrates a state where the peeling layers (10a and 10c) and the second organic layer thereon are removed to form a second organic layer on the lower electrode (2b). FIG. 3G after FIG. 3F illustrates a state where another peeling layer (11) is patterned, and a first organic layer (3c) not covered with a peeling layer is etched to be removed, thereby exposing the lower electrode (2c). FIG. 3H illustrates a state where a third organic layer (5) is formed on the exposed lower electrode (2c) and the peeling layer (11). FIG. 3I illustrates a state where the peeling layer (11) and the third organic layer (5) thereon are removed to form a third organic layer (5c) on the lower electrode (2c). FIG. 3J illustrates a case where an upper electrode (6) is formed.

The manufacturing process according to the present exemplary embodiment is different from those of the first and the second exemplary embodiments in that a second organic layer is formed by a lift-off method for leaving a peeling layer used as a mask for selectively removing a first organic layer to form a second organic layer and then removing the peeling layer. A third organic layer is also patterned by a similar lift-off method. Referring to FIGS. 3A to 3J, the method for manufacturing an organic EL device according to the present embodiment will be described. However, description of portions similar to those of the first and second exemplary embodiments will be omitted.

After formation of the lower electrodes 2a, 2b and 2c in display areas of a substrate 1 as illustrated in FIG. 3A, a first organic layer 3 and a first peeling layer 10 are sequentially formed by vacuum deposition or coating as illustrated in FIG. 3B.

For the first peeling layer 10, it is desirable to select a material highly soluble in solution in which solubility of the first organic layer 3 is low and gives no damage to the first organic layer 3 during the formation of the first peeling layer 10. When for the first organic layer 3, a material such as an arylamine derivative, a stillbene derivative, polyallylene, or a condensed polycyclic hydrocarbon compound almost dissoluble in water is used, water may be suitably used as solution (peeling liquid) for dissolving the first peeling layer 10. In such a case, for the first peeling layer 10, a water-soluble inorganic material such as LiF or NaCI, or water-soluble polymer such as polyvinyl alcohol (PVA) or polyvinyl pyrolidone may be used. A method for forming the first peeling layer 10 maybe selected according to a material. In the case of the water-soluble inorganic material, the first peeling layer 10 is formed by vacuum deposition such as vapor deposition. In the case of the water-soluble polymer, the first peeling layer 10 is formed by vacuum deposition such as vapor deposition or coating such as spin coating.

Then, a first processing step for removing the first peeling layer 10 and the first organic layer 3 located at least on the lower electrode of the second light emitting portion is executed as illustrated in FIG. 3C. In this case, as illustrated in FIG. 3C, patterning is carried out to leave the first organic layers 3a and 3c and the first peeling layer 10 of the first and third light emitting portions while removing at least the first organic layer and the first peeling layer of the second light emitting portion. As a patterning method, a photoresist protective film is formed into a desired pattern by photolithography or the ink jet method, and the first peeling layer and the first organic layer are partially and sequentially etched to be removed by using the protective film as a mask.

For an etching method of the first peeling layer 10, when the first peeling layer 10 is made of an inorganic material such as LiF, RIE using Ar gas or wet etching using water may be used. When the first peeling layer 10 is made of water-soluble polymer, RIE or plasma etching using oxygen gas, or wet etching using water can be used. In any case, a dry etching method such as RIE where a retraction amount due to side etching of the first peeling layer during etching is small is desirable. After the partial etching removable of the first peeling layer 10, the exposed first organic layer 3 is removed by RIE or plasma etching using oxygen gas. When the first peeling layer 10 is made of water-soluble polymer, the first peeling layer 10 and the first organic layer 3 can be removed en bloc during the same process.

In the first processing step, the lower electrode 2c of the third light emitting portion is not subjected to the etching process because it is covered with the first organic layer and the first peeling layer.

Then, a second organic layer 4 is formed on at least the lower electrode 2b of the second light emitting portion by vacuum deposition or coating as illustrated in FIG. 3D. Forming the second organic layer 4 by the vacuum deposition is more suitable because the first peeling layer is peeled more easily in a first peeling step described below.

Then, the first peeling step of lifting off the second organic layer 4 together with the first peeling layer 10 is carried out as illustrated in FIG. 3E. The first peeling step is executed by dipping a substrate 1 in solution where the first peeling layer 10 is dissolved. As described above, when a water-soluble material is used for the first peeling layer 10, solution containing water is used as peeling liquid. In this case, to assure contact of the first peeling layer 10 with the peeling liquid, it is desirable to set a sum total of a film thickness of the first organic layer 3 and a film thickness of the first peeling layer 10 to be sufficiently larger than that of the second organic layer 4. When the second organic layer is formed by vacuum deposition, since vapor of a deposition material travels in highly straight line in the vacuum deposition, almost no film of the second organic layer 4 is deposited on the side of the first peeling layer 10, and the side of the exposed first peeling layer 10 can surely come into contact with the peeling liquid. As a result, the first peeling layer 10 can stably and surely be dissolved. After the dissolution of the first peeling layer 10, the second organic layer 4 on the first peeling layer 10 is simultaneously lifted off from the substrate 1. As a result, a second organic layer 4b is patterned only in the second light emitting portion as illustrated in FIG. 3E.

Then, a second peeling layer 11 is formed in display areas of the substrate 1 where at least the lower electrodes 2a, 2b, 2c have been formed as illustrated in FIG. 3F. The second peeling layer 11 may be formed by using a similar material and a similar method to those of the first peeling layer.

Then, a second processing step for removing the second peeling layer 11 and the first organic layer 3c in the third light emitting portion is executed as illustrated in FIG. 3G. In the second processing step, as illustrated in FIG. 3G, patterning is carried out to leave the second peeling layer 11 of the first and second light emitting portions while removing the second peeling layer 11 and the first organic layer 3c of the third light emitting portion. As a patterning method, the method similar to that of the first peeling layer 10 may be used. The first organic layer 3c exposed after etching removal of the second peeling layer 11 is removed by RIE or plasma etching using oxygen gas. In the second processing step, the first organic layer 3c left in the third light emitting portion is etched to be removed, thereby exposing the lower electrode of the third light emitting portion.

Then, a third organic layer 5 is formed on at least the lower electrode 2c of the third light emitting portion by vacuum deposition or coating as illustrated in FIG. 3H. Forming the third organic layer 5 by the vacuum deposition is more suitable because the second peeling layer is peeled more easily in a second peeling step described below.

Then, the second peeling step of lifting off the third organic layer 5 together with the second peeling layer 11 is carried out as illustrated in FIG. 3I. As in the case of the first peeling step, the second peeling step is executed by dipping the substrate 1 in solution where the second peeling layer 11 is dissolved. As described above, when a water-soluble material is used for the second peeling layer 11, solution containing water is used as peeling liquid. In this case, to assure contact of the second peeling layer 11 with the peeling liquid, it is desirable to set a sum total of a film thickness of the first organic layer 3, a film thickness of the second organic layer 4, and a film thickness of the second peeling layer 11 to be sufficiently larger than that of the third organic layer 5. When the third organic layer is formed by vacuum deposition, since vapor of a deposition material travels in highly straight line in the vacuum deposition, almost no film of the third organic layer 5 is deposited on the side of the second peeling layer 11, and the side of the exposed peeling layer 11 can surely come into contact with the peeling liquid. As a result, the second peeling layer 11 can stably and surely be dissolved. After the dissolution of the second peeling layer 11 of an interface portion with the first organic layer 3a and the second organic layer 4b, the third organic layer 5 is lifted off from the substrate 1. As a result, a third organic layer 5c is patterned to be left only in the third light emitting portion.

After the dissolution of the second peeling layer 11, the third organic layer 5 on the second peeling layer 11 is simultaneously lifted off from the substrate 1. As a result, a third organic layer 5c is patterned only in the third light emitting portion as illustrated in FIG. 3I.

Lastly, the organic EL display device is completed by forming an upper electrode 6 on the whole surface of an area including the patterned first to third organic layers 3a, 4b, and 5c as illustrated in FIG. 3J.

In the present exemplary embodiment, between the lower electrode 2b of the second light emitting portion and the lower electrode 2c of the third light emitting portion, the numbers of processing times where etching damage occurs before formation of organic layers thereon are equal. Thus, the organic layer 4b of the second light emitting portion and the organic layer 5c of the third light emitting layer are formed on substrates approximately equal in nature, and light emission characteristics are uniform.

In the present exemplary embodiment, the second organic layer and the third organic layer are patterned by lifting-off, and accordingly none of the organic layers including the first organic layer is subjected to an etching process after coating. As a result, no surface (upper surface) of the organic layer is damaged, nor there is any need to cover the organic layer with protective layer.

Damage of the electrode or the organic layer during the etching process may occur during wet etching. When the organic layer is etched by using strongly acidic etchant, the exposed lower electrode surface is easily corroded. The present invention maybe applied to the case including such wet etching.

The exemplary embodiment has been directed to the light emitting device that includes the three organic layers. However, the present invention may be applied to a case where four or more organic layers are sequentially formed. For a lower electrode where an organic layer of a fourth color is to be formed, a first organic layer is etched to be removed, and the organic layer of a fourth color is formed. This process is repeated thereafter. Each organic layer can be formed by coating, deposition, or other arbitrary methods.

Since surface conditions of the lower electrode for the second organic layer and after except for the first organic layer are similar, there is no restriction on forming order of organic layers of different colors. Planar sizes of the organic layers do not need to be equal. Three colors of R, G, and B can be arbitrarily arrayed, such as a striped shape or a delta shape.

The exemplary embodiments have been described by taking the example of the organic EL element. However, in place of the organic EL element, a light emitting element such as an inorganic EL element, a light emitting diode (LED), or a field emission element can be used.

Hereinafter, Examples of the present invention will be described. A first exemplary example will be described.

The present exemplary example is according to the first exemplary embodiment.

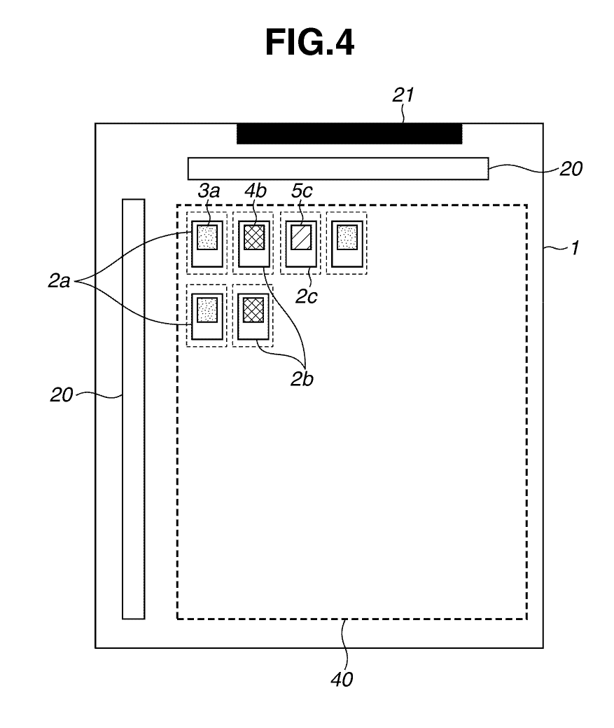

FIG. 4 is a top view illustrating an organic EL display device according to the present exemplary example. There are arranged on a substrate 1 a display area 40 in which lower electrodes 2a, 2b, and 2c and organic layers 3a, 4b, and 5c are arrayed in a matrix, an external terminal 21 for connection with the outside, and a peripheral circuit 20 configured to drive the organic EL element. Though not illustrated in FIG. 4, there are further arranged on the substrate 1 upper electrodes sandwiching the organic layers 3a, 4b, and 5c and facing the lower electrodes 2a, 2b, and 2c in the display area 40, a wiring for connecting the external terminal 21 and the peripheral circuit 20, and a pixel circuit provided for each organic EL element.

The lower electrodes 2a, 2b and 2c are periodically arrayed in a row (horizontal) direction of the display area 40. Each row is repeatedly arranged in a column (longitudinal) direction.

The lower electrodes 2a to 2c were formed by depositing an AISi alloy with 200 nm in the display area 40 of the substrate 1 by using sputtering, then patterning a photoresist by photolithography, and executing etching by RIE based on chlorine gas using the photoresist as a mask. The lower electrodes 2a, 2b, and 2c were formed into rectangular patterns of 50 μm (width)×150 μm (length), and arranged at intervals of 10 μm. Among the lower electrodes 2a, 2b and 2c, pixel separation films (not illustrated) made of polyimide resins were formed with 2 μm in thickness.

Then, as illustrated in FIG. 1B, a first organic layer 3 including a hole injection layer, a hole transport layer, and a light emitting layer was formed on the lower electrodes 2a, 2b and 2c patterned in the display area 40. The first organic layer 3 was formed by vacuum deposition. For the light emitting layer included in the first organic layer 3, a low-molecular material emitting blue light was used. A film thickness of the first organic layer 3 was 250 nm.

Though omitted in FIGS. 1A to 1G, a photoresist was formed on the first organic layer 3, and patterned by photolithography to expose a second light emitting portion in the display area.

Then, in the first processing step, RIE was executed based on oxygen gas by using the photoresist as a mask, and the first organic layer 3 formed in the second light emitting portion was removed as illustrated in FIG. 1C.

Then, as illustrated in FIG. 1D, a second organic layer 4 including a hole injection layer, a hole transport layer, and a light emitting layer was formed in the same display area as that of the first organic layer by similar vacuum deposition. The second organic layers 4 were formed on the exposed lower electrode 2b of the second light emitting portion and on the first organic layers 3a and 3c of the first light emitting portion and the third light emitting portion left without being etched in the first processing step. For the light emitting layer included in the second organic layer 4, a known low-molecular material emitting green light was used. A film thickness of the second organic layer 4 was 300 nm.

Then, a photoresist was formed on the second organic layer 4 with 0.8 μm in thickness, and patterned by photolithography to expose a first light emitting portion and a third light emitting portion.

Then, in the second processing step, first, the second organic layers 4 formed in the first light emitting portion and the third light emitting portion were removed by RIE using oxygen gas. A film thickness of the first organic layer 3 after etching of the second organic layer was 350 nm. After the etching, the photoresist on the second organic layer was removed by an organic solvent. Though not illustrated in FIGS. 1A to 1G, a photoresist was formed again on the substrate 1, and patterned by photolithography to expose only the third light emitting portion.

Then, the first organic layer 3 left on the lower electrode of the third light emitting portion was removed by RIE as illustrated in FIG. 1E. In this case, the same oxygen gas as that for removing the first organic layer 3 in the first processing step was used.

Then, a third organic layer 5 including a hole injection layer, a hole transport layer, and a light emitting layer was formed by vacuum deposition in the display area of the substrate 1. The third organic layers 5 were deposited not only on the exposed lower electrode 2c but also on the first organic layer 3a of the first light emitting portion and the second organic layer 4b of the second light emitting portion. For the light emitting layer included in the third organic layer 5, a low-molecular material emitting red light was used. A film thickness of the third organic layer 5 was 300 nm.

Then, a photoresist was formed on the substrate 1, and patterned by photolithography to expose the first light emitting portion and the second light emitting portion and cover the third light emitting portion.

Then, the third organic layers 5 formed in the first light emitting portion and the second light emitting portion were removed by RIE using oxygen gas in FIG. 1F. As a result, a first organic layer 3 left without being etched, a second organic layer 4b, and a third organic layer 5c were patterned to be formed respectively in the first light emitting portion, the second light emitting portion, and the third light emitting portion. Film thicknesses of the first organic layer 3 and the second organic layer 4 were respectively 200 nm and 250 nm.

Then, as illustrated in FIG. 1G, upper electrodes 6 were formed on the patterned first to third organic layers 3a, 4b, and 5c. Forming areas of the upper electrodes include a display area and a contact portion (not illustrated) for supplying power to the upper electrodes 6. The upper electrode 6 was formed by Ag with 20 nm in thickness by sputtering.

A silicon nitride film (not illustrated) was formed with 2000 nm in thickness on the upper electrode 6 by plasma chemical vapor deposition (CVD) to be used as a sealing film for preventing moisture infiltration through the organic layer.

Thus, an organic EL display device capable of reducing process damage to the lower electrode surface of the third light emitting portion and limited in display failure and high in definition was acquired.

A second exemplarily example will be described. The present exemplary example is according to the second exemplary embodiment. A top view is similar to FIG. 4 illustrating the first exemplary example. Description of portions such as components, sizes, and a manufacturing procedure similar to those of the first exemplary example will be omitted.

As illustrated in FIG. 2A, a plurality of lower electrodes 2a to 2c was formed on a glass substrate 1 by the same procedure as that of the first exemplary example. Film thicknesses and planar sizes were similar to those of the first exemplary example.

Then, as illustrated in FIG. 2B, a first organic layer 3 and a first protective layer 7 were sequentially formed in the lower electrodes 2a, 2b, and 2c patterned in the display area 40. For the light emitting layer included in the first organic layer 3, a low-molecular material emitting blue light was used. A film thickness of the first organic layer 3 was 250 nm. For the first protective layer 7, a silicon nitride was used, and a film thickness was 1 μm. The first protective layer 7 was formed by using the plasma CVD.

Then, a photoresist was formed on the first protective layer 7, and patterned by photolithography to expose a second light emitting portion.

Then, in the first processing step, RIE was executed by using the photoresist as a mask, and the first protective layer 7 and the first organic layer 3 formed in the second light emitting portion were continuously removed as illustrated in FIG. 2C. The first protective layer 7 made of the silicon nitride film was etched to be removed by RIE using CF4, and then the first organic layer 3 was etched by RIE using oxygen gas.

Then, as illustrated in FIG. 2D, a second organic layer 4 and a second protective layer 8 were sequentially formed on the substrate 1. The second protective layer 8 was formed by the plasma CVD. For a light emitting layer included in the second organic layer 4, a known low-molecular material emitting green light was used. A film thickness of the second organic layer 4 was 300 nm. For the second protective layer 8, as in the case of the first protective layer 7, a silicon nitride film was used, and its film thickness was 1 μm.

Then, a photoresist was formed on the second protective layer 8, and patterned by photolithography to expose a first light emitting portion.

Then, the second organic layers 4 and the second protective layer 8 formed in the first light emitting portion were continuously removed. Dry etching of the second protective layer 8 made of the silicon nitride film was carried out by RIE using CF4 gas, and then the second organic layer 4 was etched by RIE using oxygen gas.

Then, a photoresist was formed again on the substrate 1, and patterned by photolithography to expose only the third light emitting portion.

Then, the second protective layer, the second organic layer, the first protective layer 7, and the first organic layer 3 formed in the third light emitting portion were sequentially and continuously removed as illustrated in FIG. 2E. The first protective layer and the second protective layer made of the silicon nitride films were etched by RIE using CF4 gas, and the first organic layer and the second organic layer were etched by RIE using oxygen gas.

Then, as illustrated in FIG. 2F, a third organic layer 5 and a third protective layer 9 were sequentially formed in the display area of the substrate 1. For the light emitting layer included in the third organic layer 5, a low-molecular material emitting red light was used. A film thickness of the third organic layer 5 was 300 nm. For the third protective layer 9, as in the case of the first protective layer 7 and the second protective layer 8, a silicon nitride film was used, and its film thickness was 1 μm. The third protective layer 9 was formed by the plasma CVD.

Then, a photoresist was formed on the substrate 1, and patterned by photolithography to expose the first light emitting portion and the second light emitting portion in the display area 40, and cover the third light emitting portion.

Then, the third protective layer 9 and the third organic layer 5 formed in the first light emitting portion and the second light emitting portion were continuously removed to form a third protective layer and a third organic layer only in the third light emitting portion as illustrated in FIG. 2F. Specifically, the third protective layer 9 made of the silicon nitride film was etched by RIE using CF4 gas, and the third organic layer was etched by RIE using oxygen gas.

Then, in a protective layer removal step, the first protective layer 7 of the first light emitting portion, the second protective layer 8 of the second light emitting portion, and the third protective layer 9 of the third light emitting portion were removed by RIE using CF4 gas as illustrated in FIG. 2G. Film thicknesses of the respective organic layers after the first to third protective layer removal were respectively 200 nm, 250 nm, and 300 nm.

Then, as illustrated in FIG. 2H, upper electrodes 6 similar to those of the first exemplary example were formed on the patterned first to third organic layers 3a, 4b, and 5c. Further, a sealing film similar to that of the first exemplary example was formed.

A third exemplary example will be described. The present exemplary example is according to the third exemplary embodiment illustrated in FIGS. 3A to 3J. A top view of an organic EL display device of the third exemplary example is similar to FIG. 4 illustrating the first and the second exemplary examples. Description of portions similar to those of the first and the second exemplary examples will be omitted.

As illustrated in FIG. 3A, a plurality of lower electrodes 2a, 2b, and2c was formed on a glass substrate 1 as in the case of the first and the second exemplary examples.

Then, as illustrated in FIG. 3B, a first organic layer 3 was formed in the display area 40 of the substrate 1 by vacuum deposition. For a light emitting layer included in the first organic layer 3, a low-molecular material emitting blue light was used. A film thickness of the first organic layer 3 was 200 nm.

Then, a first peeling layer 10 was formed on the first organic layer 3 by spin coating. For the first peeling layer 10, polyvinyl pyrolidone was used. Polyvinyl pyrolidone aqueous solution was dried after the formation to acquire a polyvinyl pyrolidone film having a film thickness of 600 nm.

Then, a photoresist was formed on the first peeling layer 10, and patterned by photolithography to expose a second light emitting portion.

Then, in a first processing step, RIE using oxygen gas was carried out by using the photoresist as a mask to remove the first organic layer 3 formed in the second light emitting portion as illustrated in FIG. 3C.

Then, as illustrated in FIG. 3D, a second organic layer 4 was formed in the display area 40 of the substrate 1 by vacuum deposition. For a light emitting layer included in the second organic layer 4, a low-molecular material emitting green light was used. A film thickness of the second organic layer 4 was 250 nm.

Then, in a first peeling step, the substrate 1 where the second organic layer 4 has been formed was dipped in flowing water. The first peeling layer 10 was made of water-soluble polyvinyl pyrolidone. Accordingly, the first peeling layer 10 was dissolved in the flowing water, and the second organic layer 4 on the first peeling layer 10 was lifted off together with the first peeling layer 10. As a result, a second organic layer 4b was formed only in the second light emitting portion as illustrated in FIG. 3E.

Then, as illustrated in FIG. 3F, a second peeling layer 11 was formed on the substrate 1 by spin coating. For the second peeling layer 11, polyvinyl pyrolidone was used as in the case of the first peeling layer 10. Polyvinyl pyrolidone aqueous solution was dried after the formation to acquire a polyvinyl pyrolidone film having a film thickness of 600 nm.

Then, a photoresist was formed on the second peeling layer 11, and patterned by photolithography to expose a third light emitting portion in the display area 40.

Then, in a second processing step, RIE using oxygen gas was carried out by using the photoresist as a mask to remove the first organic layer 3c formed in the third second light emitting portion as illustrated in FIG. 3G.

Then, as illustrated in FIG. 3H, a third organic layer 5 was formed in the display area 40 of the substrate 1 by vacuum deposition. For a light emitting layer included in the third organic layer 5, a low-molecular material emitting red light was used. A film thickness of the third organic layer 5 was 300 nm.

Then, in a second peeling step, the substrate 1 where the third organic layer 5 has been formed was dipped in flowing water. The second peeling layer 11 was made of water-soluble polyvinyl pyrolidone. Accordingly, the second peeling layer 11 was dissolved in the flowing water, and the third organic layer 5 on the second peeling layer 11 was lifted off together with the second peeling layer 11. As a result, a third organic layer 5c was formed only in the third light emitting portion as illustrated in FIG. 3I.

Then, as illustrated in FIG. 3J, upper electrodes 6 and a sealing film similar to those of the first and the second exemplary examples were formed.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2011-217445 filed Sep. 30, 2011, which is hereby incorporated by reference herein in its entirety.

What is claimed is:

1. A method for manufacturing a light emitting device that includes, on a substrate, a plurality of lower electrodes, a first, a second and a third organic layers each formed on one of the lower electrodes to emit light of a color different from each other, and a upper electrode opposite to the lower electrodes sandwiching the first, the second or the third organic layer, the method comprising:
(1) forming the plurality of lower electrodes on the substrate;
(2) forming the first organic layer on the plurality of lower electrodes;
(3) removing the first organic layer on a certain lower electrode included in the plurality of lower electrodes to expose the lower electrode while leaving the first organic layer on the lower electrodes other than the certain lower electrode, and then forming the second organic layer on the exposed lower electrode;
(4) removing the first organic layer on another certain lower electrode different from the certain lower electrode to expose the lower electrode while leaving the first organic layer on the lower electrodes other than the certain and the another certain lower electrodes, and then forming the third organic layer on the exposed lower electrode; and
(5) forming the upper electrodes on the first to third organic layers.

2. The method for manufacturing the light emitting device according to claim 1, wherein the processing of (3) includes:
(3-1) removing the first organic layer on the certain lower electrode to expose the lower electrode;
(3-2) forming the second organic layer on the certain lower electrode and on the first organic layer left on the lower electrodes other than the certain electrode; and
(3-3) removing the second organic layer on the first organic layer while leaving the second organic layer on the certain lower electrode.

3. The method for manufacturing the light emitting device according to claim 1, wherein the processing of (4) includes:
(4-1) removing the first organic layer on the another certain lower electrode to expose the lower electrode;
(4-2) forming the third organic layer on the another certain lower electrode, on the second organic layer left on the certain lower electrode and on the first organic layer left on the lower electrodes other than the certain and the another certain lower electrodes; and
(4-3) removing the third organic layers on the first organic layer and the second organic layer while leaving the third organic layer on the another certain lower electrode.

4. The method for manufacturing the light emitting device according to claim 1, wherein
the processing of (2) includes forming a first protective layer to cover the first organic layer,
the processing of (3) includes forming a second protective layer to cover the second organic layer, and
the processing of (4) includes forming a third protective layer to cover the third organic layer, and
the method comprises removing the first to the third protective layers after the processing of (4) and before the processing of (5).

5. The method for manufacturing the light emitting device according to claim 1, wherein the processing of (3) includes:
(3-4) covering the first organic layer left on the lower electrodes other than the certain lower electrode with a first peeling layer;
(3-5) removing the first organic layer not covered with the first peeling layer to expose the lower electrode;
(3-6) forming the second organic layer on the first peeling layer and the exposed lower electrode; and
(3-7) removing the second organic layer on the first peeling layer by removing the first peeling layer.

6. The method for manufacturing the light emitting device according to claim 5, wherein the first peeling layer is water-soluble.

7. The method for manufacturing the light emitting device according to claim 1, wherein the processing of (4) includes:
(4-4) covering the first organic layer and the second organic layer located on the lower electrode other than the certain lower electrode with a second peeling layer;
(4-5) removing the first organic layer not covered with the second peeling layer to expose the lower electrode;
(4-6) forming the third organic layers on the second peeling layer and the exposed lower electrode; and
(4-7) removing the third organic layer on the second peeling layer by removing the second peeling layer.

8. The method for manufacturing the light emitting device according to claim 7, wherein the second peeling layer is water-soluble.

9. The method for manufacturing the light emitting device according to claim 1, wherein in the processing of (3) and (4), the first organic layers are removed by dry etching using the same etching gas.

10. The method for manufacturing the light emitting device according to claim 1, wherein a surface of the lower electrode is one of an aluminum alloy film, a silver alloy film, and a transparent conductive oxide film.
